(19) United States
(12) Patent Application Publication
(10) Pub. No.: US 2026/0066859 A1
(43) Pub. Date: Mar. 5, 2026

(54) BALUN AND POWER AMPLIFIER CIRCUIT

(71) Applicant: Murata Manufacturing Co., Ltd., Nagaokakyo-shi (JP)

(72) Inventor: Kenji TAHARA, Nagaokakyo-shi (JP)

(21) Appl. No.: 19/295,794

(22) Filed: Aug. 11, 2025

(30) Foreign Application Priority Data
Sep. 3, 2024 (JP) 2024-151531

(51) Int. Cl. H03F 3/45; H03F 1/56; H03F 3/24

(52) U.S. Cl. CPC H03F 3/45085; H03F 1/565; H03F 3/245; H03F 2200/06; H03F 2200/09

(57) ABSTRACT

A balun includes a first wire including a first end connected to a first balanced line transmitting one of balanced signals and a second end connected to a first reference potential; a second wire including a first end connected to a second balanced line transmitting another one of the balanced signals and a second end connected to the first reference potential; a third wire that includes a first end and an open second end and is electromagnetically coupled to the first wire; a fourth wire that includes a first end connected to the first end of the third wire and a second end connected to an unbalanced line transmitting an unbalanced signal and is electromagnetically coupled to the second wire; a first capacitor connected in parallel with a part of the first wire; and a second capacitor connected in parallel with a part of the second wire.

### CROSS REFERENCE TO RELATED APPLICATION

This application claims priority from Japanese Patent Application No. 2024-151531, filed on Sep. 3, 2024. The content of this applications is incorporated herein by reference in its entirety.

### BACKGROUND OF THE DISCLOSURE

### 1. Field of the Disclosure

The present disclosure relates to a balun and a power amplifier circuit.

### 2. Description of the Related Art

A known differential amplification device is used, for example, as a power amplification device for wireless communication (see, for example, Japanese Unexamined Patent Application Publication No. 2023-068288).

### BRIEF SUMMARY OF THE DISCLOSURE

A transformer described in Japanese Unexamined Patent Application Publication No. 2023-068288 includes an input-side inductor and an output-side inductor. A first end of the input-side inductor is connected to an output terminal of a first amplifier. A second end of the input-side inductor is connected to an output terminal of a second amplifier. A first end of the output-side inductor is connected to an output terminal via a matching circuit. A second end of the output-side inductor is connected to a reference potential.

In the transformer described in Japanese Unexamined Patent Application Publication No. 2023-068288, the input-side inductor and the output-side inductor are electromagnetically coupled to each other. Here, when a transformer, which includes an input-side inductor and an output-side inductor implemented by coils, is used in a radio frequency band, such as a sub-terahertz band, the influence of parasitic capacitance between lines is significant. Consequently, the transformer may be unable to achieve its intrinsic performance. Using a Marchand balun instead of a transformer may solve this problem but causes a new problem in which amplifiers operate in inverse Class F.

Also, to enable amplifiers connected to the Marchand balun to operate in Class F, LC series circuits may be provided in parallel behind the amplifiers. However, this configuration increases the circuit size due to the addition of the LC series circuits and is therefore undesirable.

The present disclosure has been made in view of the above problem, and a possible benefit of the present disclosure is to provide a balun and a power amplifier circuit that enable amplifiers to operate in Class F while reducing an increase in the circuit size.

A balun according to an aspect of the present disclosure includes a first wire including a first end connected to a first balanced line transmitting one of balanced signals and a second end connected to a first reference potential; a second wire including a first end connected to a second balanced line transmitting another one of the balanced signals and a second end connected to the first reference potential; a third wire that includes a first end and an open second end and is electromagnetically coupled to the first wire; a fourth wire that includes a first end connected to the first end of the third wire and a second end connected to an unbalanced line transmitting an unbalanced signal and is electromagnetically coupled to the second wire; a first capacitor connected in parallel with a part of the first wire; and a second capacitor connected in parallel with a part of the second wire.

A power amplifier circuit according to another aspect of the present disclosure includes a first amplifier that amplifies a first signal and outputs a first amplified signal from a first output terminal; a second amplifier that amplifies a second signal, which is out of phase with the first signal, and outputs a second amplified signal from a second output terminal; a first wire including a first end connected to the first output terminal and a second end connected to a first reference potential; a second wire including a first end connected to the second output terminal and a second end connected to the first reference potential; a third wire that includes a first end and an open second end and is electromagnetically coupled to the first wire; a fourth wire that includes a first end connected to the first end of the third wire and a second end connected to an output terminal and is electromagnetically coupled to the second wire; a first capacitor connected in parallel with a part of the first wire; and a second capacitor connected in parallel with a part of the second wire.

The present disclosure makes it possible to provide a balun and a power amplifier circuit that enable amplifiers to operate in Class F while reducing an increase in the circuit size.

### BRIEF DESCRIPTION OF THE SEVERAL VIEWS OF THE DRAWINGS

FIG. 1 is a circuit diagram of a power amplifier circuit 201;

FIG. 2 is a circuit diagram of a power amplifier circuit 291 according to a comparative example;

FIG. 3 is a Smith chart showing simulation results of the frequency variation of S11 in the power amplifier circuit 291 according to the comparative example;

FIG. 4 is a circuit diagram of a power amplifier circuit 292 according to a comparative example;

FIG. 5 is a Smith chart showing simulation results of the frequency variation of S11 in the power amplifier circuit 201;

FIG. 6 is a diagram showing simulation results of the frequency variation of S21 in the power amplifier circuit 291 according to the comparative example;

FIG. 7 is a diagram showing simulation results of the frequency variation of S21 in the power amplifier circuit 201;

FIG. 8 is a plan view of a balun 101 seen from above;

FIG. 9 is a plan view of a portion around a capacitor 121 of the balun 101 seen from above;

FIG. 10 is a perspective view of a portion around the capacitor 121 of the balun 101;

FIG. 11 is a circuit diagram of a power amplifier circuit 202; and

FIG. 12 is a circuit diagram of a power amplifier circuit 203.

### DETAILED DESCRIPTION OF THE DISCLOSURE

Embodiments of the present disclosure are described in detail below with reference to the drawings. The same reference number is assigned to the same components, and repeated descriptions of those components are omitted as far as possible.

### First Embodiment

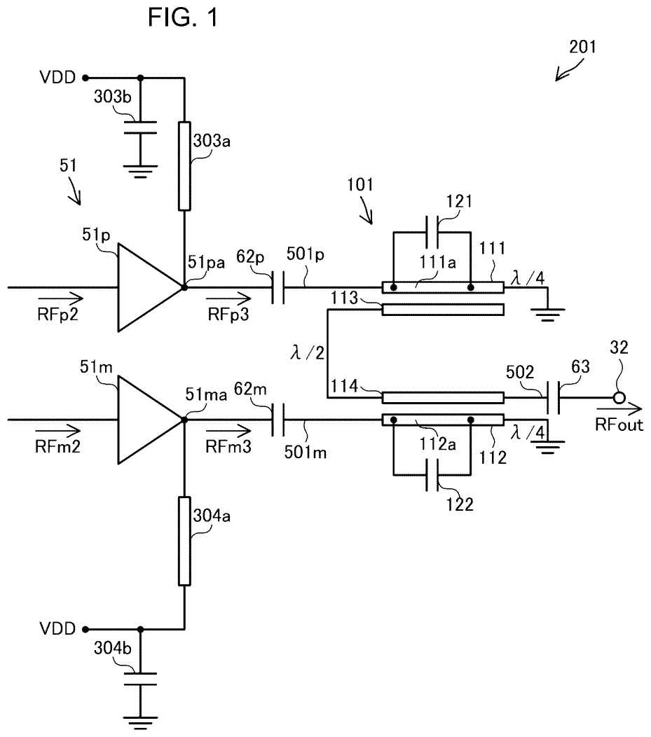

A power amplifier circuit 201 according to a first embodiment is described. FIG. 1 is a circuit diagram of the power amplifier circuit 201. As illustrated in FIG. 1, the power amplifier circuit 201 includes a differential pair 51, capacitors 62p, 62m, and 63, a balun 101, wires 303a and 304a, and capacitors 303b and 304b.

The differential pair 51 includes amplifiers 51p (first amplifier) and 51m (second amplifier). Each of the amplifiers 51p and 51m includes an amplification transistor (not shown). The balun 101 includes wires 111 (first wire), 112 (second wire), 113 (third wire), and 114 (fourth wire) and capacitors 121 (first capacitor) and 122 (second capacitor).

In the present embodiment, each transistor is implemented by, for example, a bipolar transistor, such as a heterojunction bipolar transistor (HBT). Alternatively, each transistor may be implemented by any other type of transistor, such as a metal-oxide-semiconductor field-effect transistor (MOSFET). In this case, a base, a collector, and an emitter in the descriptions below are substituted by a gate, a drain, and a source, respectively.

The differential pair 51 of the power amplifier circuit 201 amplifies signals RFp2 (first signal) and RFm2 (second signal), which are balanced signals. The frequency of each balanced signal is included in, for example, the sub-terahertz band. Specifically, the frequency of each balanced signal is included in a range from 90 GHz to 300 GHz.

The signal RFm2 is out of phase with the signal RFp2. In the present embodiment, the signal RFm2 is out of phase with the signal RFp2 by, for example, about 180°.

Specifically, the amplifier 51p of the differential pair 51 amplifies the signal RFp2 supplied from a preceding circuit and outputs an amplified signal RFp3 (first amplified signal) from an output terminal 51pa (first output terminal). An amplification transistor included in the amplifier 51p operates on a power supply voltage VDD that is supplied via the wire 303a, which functions as an inductor, and the output terminal 51pa. The capacitor 303b is a bypass capacitor and includes a first end to which the power supply voltage VDD is supplied and a second end connected to the ground. Here, the ground potential is an example of a first reference potential.

The amplifier 51m amplifies the signal RFm2 supplied from a preceding circuit and outputs an amplified signal RFm3 (second amplified signal) from an output terminal 51ma (second output terminal). An amplification transistor included in the amplifier 51m operates on a power supply voltage VDD that is supplied via the wire 304a, which functions as an inductor, and the output terminal 51ma. The capacitor 304b is a bypass capacitor and includes a first end to which the power supply voltage VDD is supplied and a second end connected to the ground.

A balanced line 501p (first balanced line) includes a first end, which is connected to the output terminal 51pa of the amplifier 51p, and a second end and transmits one of the balanced signals, i.e., the amplified signal RFp3.

A balanced line 501m (second balanced line) includes a first end, which is connected to the output terminal 51ma of the amplifier 51m, and a second end and transmits the other one of the balanced signals, i.e., the amplified signal RFm3.

The capacitors 62p and 62m have, for example, a DC blocking function and are provided on the balanced lines 501p and 501m, respectively. The capacitors 62p and 62m may also have a function to match the impedance between the differential pair 51 and the balun 101.

Specifically, the capacitor 62p includes a first end connected to the output terminal 51pa of the amplifier 51p via a part of the balanced line 501p and a second end connected to the wire 111 via another part of the balanced line 501p.

The capacitor 62m has a first end connected to the output terminal 51ma of the amplifier 51m via a part of the balanced line 501m and a second end connected to the wire 112 via another part of the balanced line 501m.

The balun 101 converts the amplified signals RFp3 and RFm3 supplied from the differential pair 51 into an output signal RFout, which is an unbalanced signal, i.e., a single-ended signal. Also, the balun 101 matches the impedance between the differential pair 51 and a circuit, such as an antenna, disposed downstream of the output terminal 32.

Specifically, the wire 111 of the balun 101 includes a first end connected to the second end of the balanced line 501p and a second end connected to the ground.

The wire 112 includes a first end connected to the second end of the balanced line 501m and a second end connected to the ground.

Each of the wires 111 and 112 is a quarter-wave line. Specifically, the time taken by each of the amplified signals RFp3 and RFm3 to propagate from the first end to the second end of the corresponding one of the wires 111 and 112 is substantially one quarter of the period of the corresponding one of the amplified signals RFp3 and RFm3. In other words, the electrical length of each of the wires 111 and 112 is substantially one quarter of the wavelength of the corresponding one of the amplified signals RFp3 and RFm3.

The wire 113 includes a first end and an open second end. The wire 113 is electromagnetically coupled to the wire 111.

The wire 114 includes a first end connected to the first end of the wire 113 and a second end connected to an unbalanced line 502 that transmits the output signal RFout. The wire 114 is electromagnetically coupled to the wire 112.

The unbalanced line 502 includes a first end connected to the second end of the wire 114 and a second end connected to the output terminal 32.

The capacitor 63 is provided on the unbalanced line 502. Specifically, the capacitor 63 includes a first end connected to the second end of the wire 114 via a part of the unbalanced line 502 and a second end connected to the output terminal 32 via another part of the unbalanced line 502.

A wire formed by the combination of the wires 113 and 114 is a half-wave line. Specifically, the time taken by the output signal RFout to propagate from the second end of the wire 113 to the second end of the wire 114 is substantially one half of the period of the output signal RFout. In other words, the electrical length from the second end of the wire 113 to the second end of the wire 114 is substantially one half of the wavelength of the output signal RFout.

The capacitor 121 is connected in parallel with a part 111a of the wire 111. Specifically, the part 111a is located between the first end and the second end of the wire 111. Alternatively, the part 111a may include one of the first end and the second end of the wire 111.

The capacitor 122 is connected in parallel with a part 112a of the wire 112. Specifically, the part 112a is located between the first end and the second end of the wire 112. Alternatively, the part 112a may include one of the first end and the second end of the wire 112. The electrical length of the part 111a is substantially equal to the electrical length of the part 112a.

### Comparative Examples

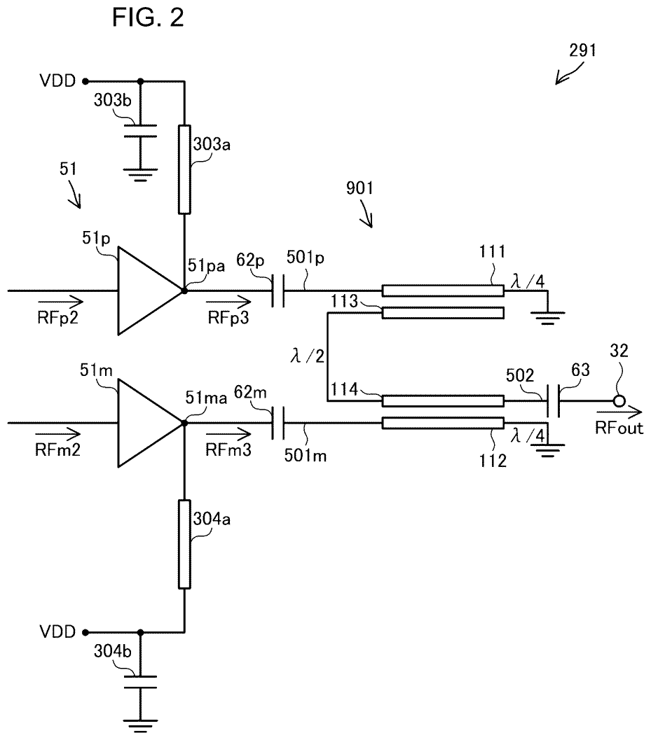

A power amplifier circuit 291 according to a comparative example is described. FIG. 2 is a circuit diagram of the power amplifier circuit 291 according to the comparative example. The power amplifier circuit 291 differs from the power amplifier circuit 201 (see FIG. 1) in that the balun 101 is replaced with a balun 901. Compared with the balun 101 (see FIG. 1), the balun 901 does not include the capacitors 121 and 122.

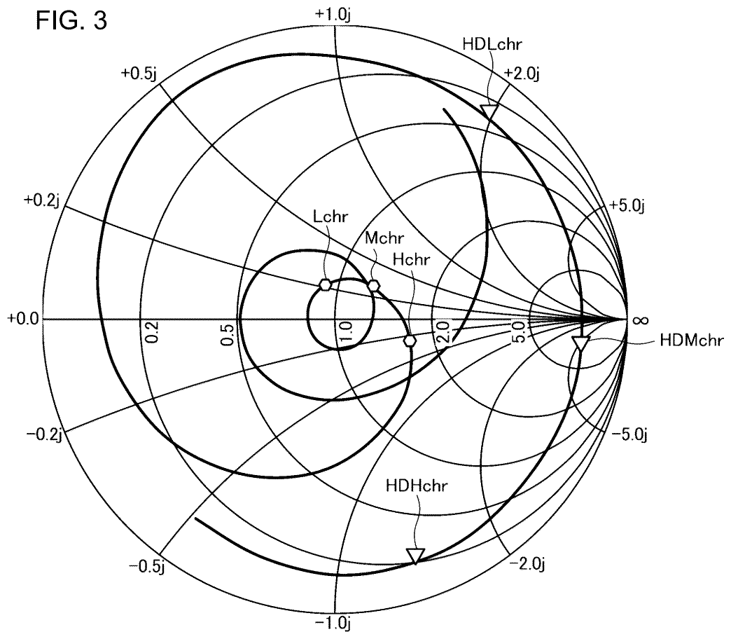

FIG. 3 is a Smith chart showing simulation results of the frequency variation of S11 in the power amplifier circuit 291 according to the comparative example. Here, S11 is a scattering(S) parameter of a signal that is inputted from the amplifier 51p to the capacitor 62p. In the descriptions below, a signal inputted from the amplifier 51p to the capacitor 62p is used as an example. However, the descriptions also apply to a signal inputted from the amplifier 51m to the capacitor 62m.

As illustrated in FIG. 3, values of S11 at frequencies of 120 GHz, 130 GHz, and 140 GHz, which are included in the fundamental wave band of the amplified signal RFp3, are represented by Lchr, Mchr, and Hchr, respectively.

Values of S11 at frequencies of 240 GHz, 260 GHZ, and 280 GHz, which are included in the second-order harmonic wave band of the amplified signal RFp3, are represented by HDLchr, HDMchr, and HDHchr, respectively.

The impedance between the differential pair 51 and a circuit downstream of the output terminal 32 is matched, and the reflection of the fundamental wave of the amplified signal RFp3 is reduced. On the other hand, because the shorted quarter-wave line is connected to the output terminal 51ma of the amplifier 51p, the impedance of the second-order harmonic wave of the amplified signal RFp3 is high. For this reason, in the power amplifier circuit 291, the amplifier 50p can operate only in inverse Class F.

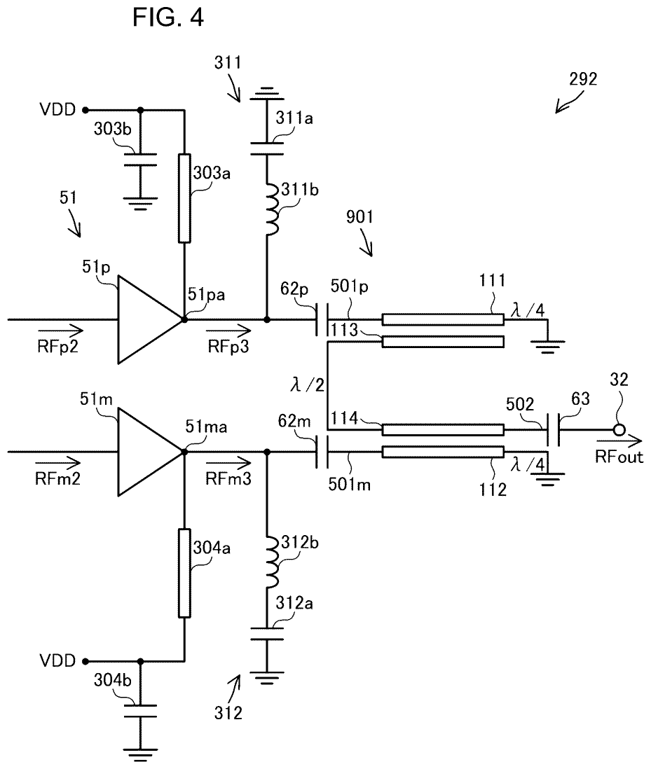

FIG. 4 illustrates a circuit diagram of a power amplifier circuit 292 according to a comparative example. Compared with the power amplifier circuit 291 (see FIG. 2), the power amplifier circuit 292 additionally includes LC series circuits 311 and 312.

The LC series circuit 311 includes a capacitor 311a and an inductor 311b that are connected in series between the output terminal 51pa of the amplifier 51p and the ground.

The LC series circuit 312 includes a capacitor 312a and an inductor 312b that are connected in series between the output terminal 51ma of the amplifier 51m and the ground.

The amplifiers 50p and 50m can be operated in Class F by adjusting the circuit constants of the LC series circuits 311 and 312 to short at the second-order harmonic wave of the amplified signal RFp3 and thereby causing the LC series circuits 311 and 312 to function as notch filters.

However, when the Q values of the LC series circuits 311 and 312 are not high, the loss in the fundamental wave band of the amplified signal RFp3 may increase, which may lead to the degradation of the output power and reduction in efficiency.

Also, providing the LC series circuits 311 and 312 increases the circuit size. When, for example, an antenna in the sub-terahertz band is implemented by a patch antenna, because the size of the patch antenna is about 1.1 mm, any method that increases the circuit size is not preferable.

Furthermore, it is difficult to form a notch filter with a high Q value in a semiconductor chip that amplifies signals in the sub-terahertz band.

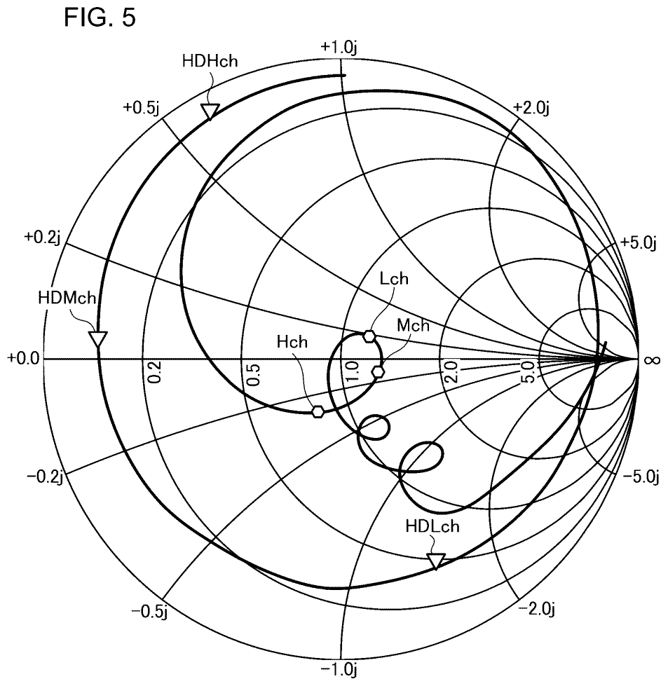

FIG. 5 is a Smith chart showing simulation results of the frequency variation of S11 in the power amplifier circuit 201.

As illustrated in FIG. 5, values of S11 at frequencies of 120 GHZ, 130 GHz, and 140 GHz, which are included in the fundamental wave band of the amplified signal RFp3, are represented by Lch, Mch, and Hch, respectively.

Values of S11 at frequencies of 240 GHZ, 260 GHZ, and 280 GHz, which are included in the second-order harmonic wave band of the amplified signal RFp3, are represented by HDLch, HDMch, and HDHch, respectively.

As illustrated in FIGS. 1 and 5, in the power amplifier circuit 201, the capacitor 121 is provided in parallel with the part 111a of the wire 111. In the fundamental wave band of the amplified signal RFp3, the part 111a of the wire 111 and the capacitor 121 function as an LC tank circuit and can properly match the impedance between the differential pair 51 and a circuit downstream of the output terminal 32. This makes it possible to reduce the reflection of the fundamental wave of the amplified signal RFp3.

In the second-order harmonic wave band of the amplified signal RFp3, the parallel circuit formed by the part 111a of the wire 111 and the capacitor 121 prominently exhibits the property of a capacitor, and therefore the wire 111 and the capacitor 121 together function as with an LC series circuit.

That is, the wire 111 and the capacitor 121 can function as a notch filter that shorts in the second-order harmonic wave band of the amplified signal RFp3. This makes it possible to reduce the impedance in the second-order harmonic wave band of the amplified signal RFp3 and thereby enables the amplifier 50p to operate in Class F.

Thus, the above configuration enables the amplifier 50p to operate in Class F while reducing an increase in the circuit size. The same applies to the amplifier 50m.

FIG. 6 is a diagram showing simulation results of the frequency variation of S21 in the power amplifier circuit 291 according to the comparative example. Here, S21 is an S parameter of a signal that is outputted from the amplifier 51p and passes through the balun 901. The vertical axis indicates S21 in “dB”. The horizontal axis indicates the frequency in “GHz”.

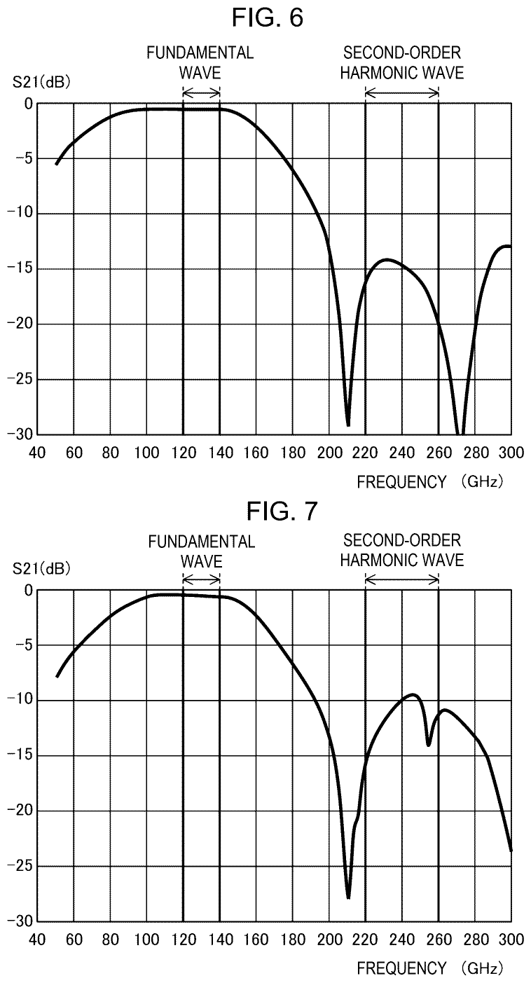

FIG. 7 is a diagram showing simulation results of the frequency variation of S21 in the power amplifier circuit 201. Here, S21 is an S parameter of a signal that is outputted from the amplifier 51p and passes through the balun 101. The axis labels in FIG. 7 are the same as those in FIG. 6.

As shown in FIGS. 6 and 7, in the second-order harmonic wave band of the amplified signal RFp3, because the impedance of the power amplifier circuit 201 is close to zero, S21 in the power amplifier circuit 201 is greater than that in the power amplifier circuit 291.

### Layout of Balun 101

A layout of the balun 101 is described. Each diagram may include arrows indicating an x-axis, a y-axis, and a z-axis. The x-axis, the y-axis, and the z-axis form a right-handed three-dimensional orthogonal coordinate system. In the descriptions below, a direction indicated by the arrow of the x-axis is referred to as a positive x-axis side, and a direction opposite to the arrow is referred to as a negative x-axis side. This terminology also applies to other axes. The positive z-axis side and the negative z-axis side may also be referred to as “upper side” and “lower side”, respectively. Furthermore, the planes that are orthogonal to the x-axis, the y-axis, and the z-axis may be referred to as a yz plane, a zx plane, and an xy plane, respectively. Here, the direction of clockwise rotation in a view from above is defined as a clockwise direction cw. Also, the direction of counterclockwise rotation in a view from above is defined as a counterclockwise direction ccw.

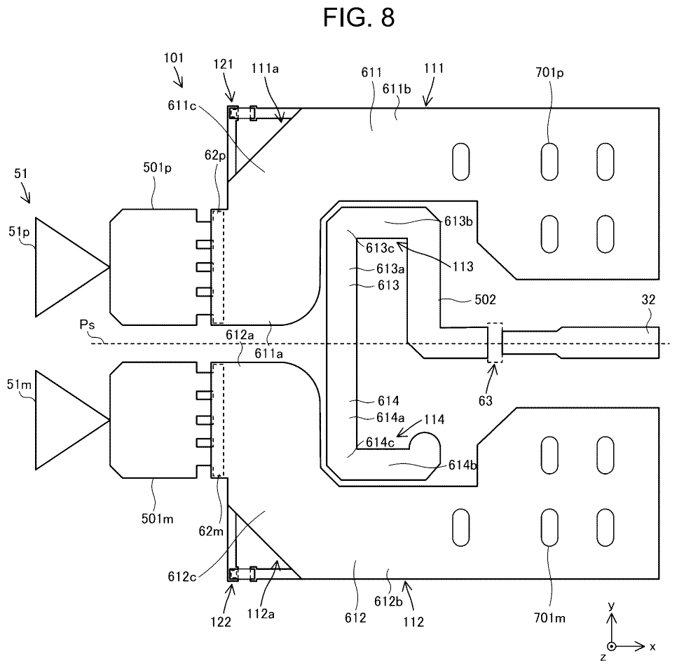

FIG. 8 is a plan view of the balun 101 seen from above. As illustrated in FIG. 8, the wires 111, 112, 113, and 114 are formed by metal electrodes 611 (first conductive component), 612 (second conductive component), 613 (third conductive component), and 614 (fourth conductive component), respectively.

Specifically, the wire 111 is formed by the metal electrode 611 that extends from the first end of the wire 111 to the second end of the wire 111. The wire 112 is formed by the metal electrode 612 that extends from the first end of the wire 112 to the second end of the wire 112. The wire 113 is formed by the metal electrode 613 that extends from the first end of the wire 113 to the second end of the wire 113. The wire 114 is formed by the metal electrode 614 that extends from the first end of the wire 114 to the second end of the wire 114.

The metal electrodes 611, 612, 613, and 614 are provided along a first surface. In the present embodiment, the first surface is substantially parallel to the xy plane. The first surface is, for example, a surface of a semiconductor chip. Alternatively, the first surface may be a surface of an insulating layer provided inside of a semiconductor chip.

The metal electrodes 611 and 612 are symmetrical with respect to a plane (hereafter may be referred to as a symmetry plane Ps) that is parallel to the zx plane. The capacitors 62p and 62m are symmetrical with respect to the symmetry plane Ps. The balanced lines 501p and 501m are symmetrical with respect to the symmetry plane Ps. The capacitors 121 and 122 are symmetrical with respect to the symmetry plane Ps.

The metal electrode 611 includes extension parts 611a (first extension part) and 611b (second extension part) and a corner part 611c (first corner part). The corner part 611c forms the part 111a of the wire 111, and the extension direction of the metal electrode 611 changes at the corner part 611c.

In the present embodiment, the extension direction of the metal electrode 611, which extends from the first end of the wire 111 to the second end of the wire 111, changes from the positive y-axis direction to the positive x-axis direction at the corner part 611c.

The metal electrode 612 includes extension parts 612a (third extension part) and 612b (fourth extension part) and a corner part 612c (second corner part). The corner part 612c forms the part 112a of the wire 112, and the extension direction of the metal electrode 612 changes at the corner part 612c.

In the present embodiment, the extension direction of the metal electrode 612, which extends from the first end of the wire 112 to the second end of the wire 112, changes from the negative y-axis direction to the positive x-axis direction at the corner part 612c.

The extension part 611a and the extension part 612a extend toward each other from the corner part 611c and the corner part 612c, respectively.

Specifically, the extension part 611a extends from the corner part 611c in the negative y-axis direction. The balanced line 501p is connected to the negative x-axis side of the extension part 611a. The capacitor 62p is provided on the balanced line 501p. The balanced line 501p electrically connects the extension part 611a to the amplifier 51p.

The extension part 612a extends from the corner part 612c in the positive y-axis direction. The balanced line 501m is connected to the negative x-axis side of the extension part 612a. The capacitor 62m is provided on the balanced line 501m. The balanced line 501m electrically connects the extension part 612a to the amplifier 51m.

The extension part 611b and the extension part 612b extend in the same direction from the corner part 611c and the corner part 612c, respectively.

Specifically, the extension part 611b extends from the corner part 611c in the positive x-axis direction. A part of the extension part 611b on the positive x-axis side is electrically connected to an electrode with a ground potential through interlayer vias 701p.

The extension part 612b extends from the corner part 612c in the positive x-axis direction. A part of the extension part 612b on the positive x-axis side is electrically connected to an electrode with a ground potential through interlayer vias 701m.

The metal electrode 613 includes extension parts 613a and 613b and a corner part 613c (third corner part). The corner part 613c is disposed inward of the corner part 611c and extends alongside the corner part 611c.

In the present embodiment, the extension direction of the metal electrode 613, which extends from the first end of the wire 113 to the second end of the wire 113, changes from the positive y-axis direction to the positive x-axis direction at the corner part 613c.

The metal electrode 614 includes extension parts 614a and 614b and a corner part 614c (fourth corner part). The corner parts 613c and 614c are symmetrical with respect to the symmetry plane Ps. The corner part 614c is disposed inward of the corner part 612c and extends alongside the corner part 612c.

In the present embodiment, the extension direction of the metal electrode 614, which extends from the first end of the wire 114 to the second end of the wire 114, changes from the negative y-axis direction to the positive x-axis direction at the corner part 614c.

The extension parts 613a and 614a extend toward each other from the corner parts 613c and 614c, respectively. Specifically, the extension part 613a is disposed on the positive x-axis side of the extension part 611a and extends from the corner part 613c in the negative y-axis direction alongside the extension part 611a. The extension part 614a is disposed on the positive x-axis side of the extension part 612a, extends from the corner part 614c in the positive y-axis direction alongside the extension part 612a, and connects with the extension part 613a.

The extension parts 613b and 614b extend in the same direction from the corner parts 613c and 614c, respectively. Specifically, the extension part 613b is disposed on the negative y-axis side of the extension part 611b and extends from the corner part 613c in the positive x-axis direction alongside the extension part 611b. The extension part 614b is disposed on the positive y-axis side of the extension part 612b and extends from the corner part 614c in the positive x-axis direction alongside the extension part 612b.

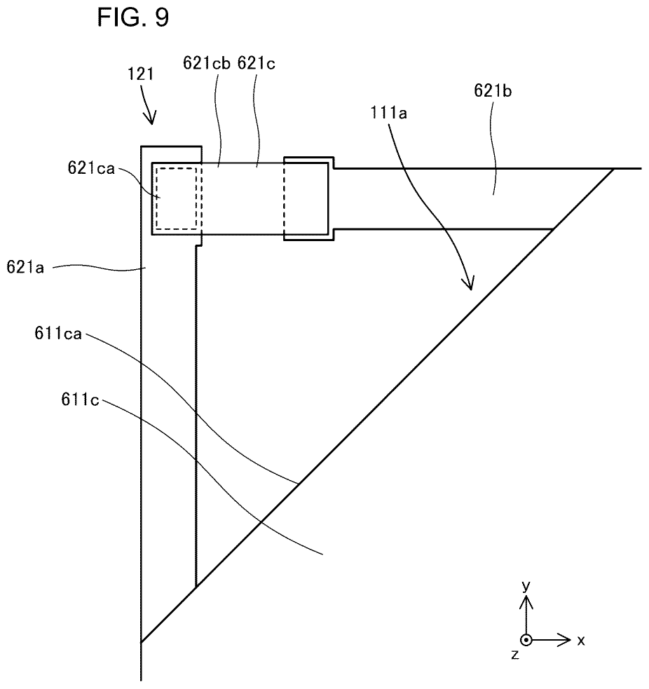

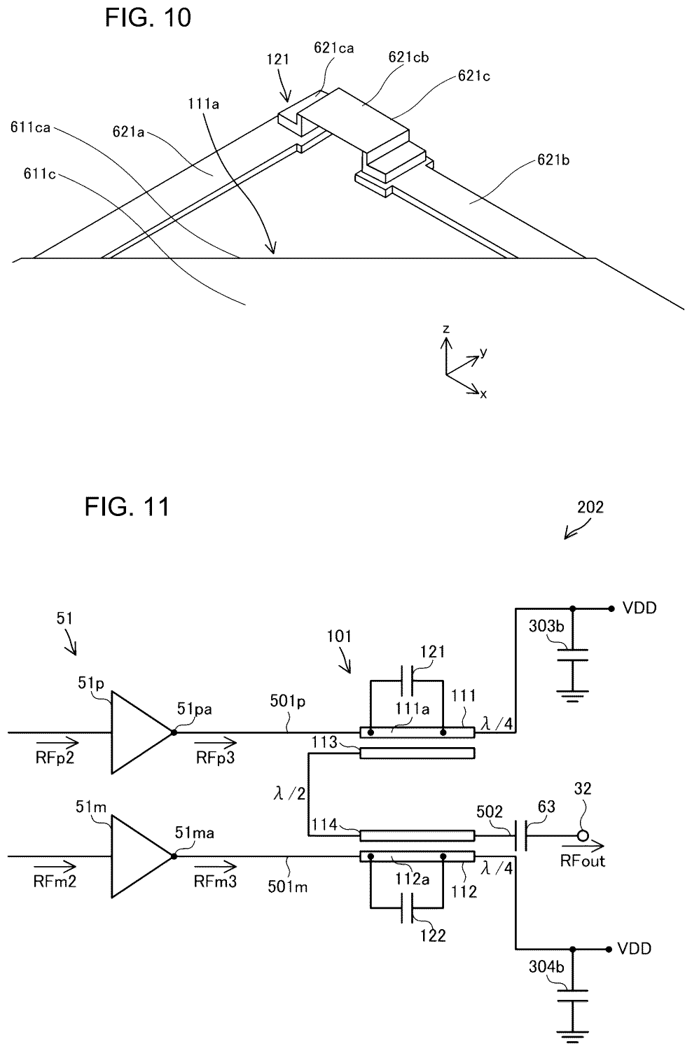

FIG. 9 is a plan view of a portion around the capacitor 121 of the balun 101 seen from above. FIG. 10 is a perspective view of a portion around the capacitor 121 of the balun 101.

As illustrated in FIGS. 9 and 10, the capacitor 121 is disposed outward of the corner part 611c.

Specifically, the outer side of the corner part 611c is diagonally truncated. In the descriptions below, the diagonally truncated portion of the corner part 611c may be referred to as a truncated corner part 611ca.

A metal electrode 621a extending in the positive y-axis direction is connected to an end of the truncated corner part 611ca that is located on the negative x-axis side and the negative y-axis side. A part of the metal electrode 621a on the positive y-axis side forms the lower electrode of the capacitor 121.

A metal electrode 621b extending in the negative x-axis direction is connected to an end of the truncated corner part 611ca that is located on the positive x-axis side and the positive y-axis side.

A bridge part 621c is provided at the negative x-axis end of the metal electrode 621b. A metal electrode 621ca, which forms the upper electrode of the capacitor 121, is provided on the negative x-axis side of the bridge part 621c. The metal electrode 621ca faces the part of the metal electrode 621a on the positive y-axis side across an insulator.

The bridge part 621c electrically connects the metal electrode 621ca to the negative x-axis end of the metal electrode 621b via a metal electrode 621cb that is included in a conductive layer above the conductive layer including the metal electrodes 621a and 621b.

As illustrated in FIG. 8, the capacitor 122 is disposed outward of the corner part 612c. The configuration of the capacitor 122 is substantially the same as that of the capacitor 121, and therefore the detailed descriptions of the capacitor 122 are omitted.

### Second Embodiment

A power amplifier circuit 202 according to a second embodiment is described. In the second and subsequent embodiments, descriptions of features that are the same as those in the first embodiment are omitted, and only the differences are described. In particular, the description of the same effect provided by the same feature is not repeated for each embodiment.

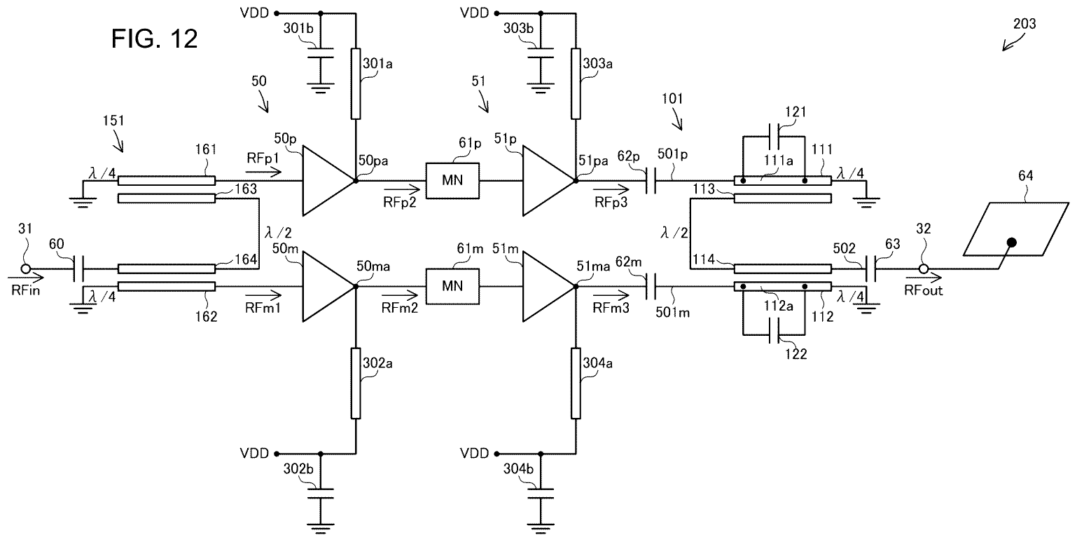

FIG. 11 is a circuit diagram of the power amplifier circuit 202. As illustrated in FIG. 11, the power amplifier circuit 202 differs from the power amplifier circuit 201 according to the first embodiment in that the power supply voltage VDD (first reference potential) is supplied from the second end of the wire 111 and the second end of the wire 112.

Different from the power amplifier circuit 201 illustrated in FIG. 1, the power amplifier circuit 202 does not include the capacitors 62p and 62m and the wires 303a and 304a.

A first end of the wire 111 is connected to the output terminal 51pa of the amplifier 51p via the balanced line 501p. The power supply voltage VDD is supplied to a second end of the wire 111. The capacitor 303b includes a first end connected to the second end of the wire 111 and a second end connected to the ground.

A first end of the wire 112 is connected to the output terminal 51ma of the amplifier 51m via the balanced line 501m. The power supply voltage VDD is supplied to a second end of the wire 112. The capacitor 304b includes a first end connected to the second end of the wire 112 and a second end connected to the ground.

This configuration enables the wires 111 and 112 to also function as choke coils. Also, this configuration makes it possible to remove the capacitors 62p and 62m for DC blocking. This in turn makes it possible to make the circuit size of the power amplifier circuit 202 smaller than that of the power amplifier circuit 201.

### Third Embodiment

A power amplifier circuit according to a third embodiment is described. FIG. 12 is a circuit diagram of a power amplifier circuit 203. As illustrated in FIG. 12, different from the power amplifier circuit 201 according to the first embodiment, the power amplifier circuit 203 additionally includes a driver-stage differential pair and an antenna.

Compared with the power amplifier circuit 201 illustrated in FIG. 1, the power amplifier circuit 203 additionally includes a differential pair 50, a capacitor 60, inter-stage matching circuits 61p and 61m, a patch antenna 64, a balun 151, wires 301a and 302a, and capacitors 301b and 302b.

The differential pair 50 includes amplifiers 50p and 50m. Each of the amplifiers 50p and 50m includes an amplification transistor (not shown). The balun 151 includes wires 161, 162, 163, and 164.

The balun 151 converts an input signal RFin, which is a single-ended signal, into signals RFp1 and RFm1, which are balanced signals. Also, the balun 151 matches the impedance between a circuit disposed upstream of an input terminal 31 and the differential pair 50.

The wires 161, 162, 163, and 164 of the balun 151 are substantially the same as the wires 111, 112, 113, and 114 of the balun 101, respectively.

The wire 163 includes a first end and an open second end. The wire 164 includes a first end connected to the first end of the wire 163 and a second end to which the input signal RFin is supplied from the input terminal 31 via the capacitor 60.

The wire 161 includes a first end supplying a signal RFp1 to the amplifier 50p and a second end connected to the ground, and is electromagnetically coupled to the wire 163.

The wire 162 includes a first end supplying a signal RFm1 to the amplifier 50m and a second end connected to ground, and is electromagnetically coupled to the wire 164.

The amplifier 50p of the differential pair 50 amplifies the signal RFp1 supplied from the second end of the wire 161 and outputs an amplified signal RFp2 from an output terminal 50pa. An amplification transistor included in the amplifier 50p operates on the power supply voltage VDD that is supplied via the wire 301a, which functions as an inductor, and the output terminal 50pa. The capacitor 301b is a bypass capacitor and includes a first end to which the power supply voltage VDD is supplied and a second end connected to the ground.

The amplifier 50m amplifies the signal RFm1 supplied from the second end of the wire 162 and outputs an amplified signal RFm2 from an output terminal 50ma. An amplification transistor included in the amplifier 50m operates on the power supply voltage VDD that is supplied via the wire 302a, which functions as an inductor, and the output terminal 50ma. The capacitor 302b is a bypass capacitor and includes a first end to which the power supply voltage VDD is supplied and a second end connected to the ground.

The inter-stage matching circuit 61p is disposed between the amplifier 51p and the amplifier 50p and matches the impedance between the amplifier 51p and the amplifier 50p. The inter-stage matching circuit 61m is disposed between the amplifier 51m and the amplifier 50m and matches the impedance between the amplifier 51m and the amplifier 50m.

The patch antenna 64 is connected to the output terminal 32. The patch antenna 64 functions as a load for the power amplifier circuit 203.

In the configuration of the present embodiment described above, the balun 151 is provided on the input side. However, the present embodiment is not limited to this example. Another balun 101 including capacitors connected in parallel with parts of wires may instead be provided on the input side.

Embodiments of the present disclosure are described above. In the balun 101, the wire 111 includes the first end connected to the balanced line 501p transmitting one of balanced signals and the second end connected to the first reference potential. The wire 112 includes the first end connected to the balanced line 501m transmitting the other one of the balanced signals and the second end connected to the first reference potential. The wire 113 includes the first end and the open second end and is electromagnetically coupled to the wire 111. The wire 114 includes the first end connected to the first end of the wire 113 and the second end connected to the unbalanced line 502, which transmits an unbalanced signal, and is electromagnetically coupled to the wire 112. The capacitor 121 is connected in parallel with the part 111a of the wire 111. The capacitor 122 is connected in parallel with the part 112a of the wire 112.

With this configuration in which the capacitor 121 is disposed in parallel with the part 111a of the wire 111, the part 111a of the wire 111 and the capacitor 121 can function as an LC tank circuit in the fundamental wave band of the balanced signals. Similarly, with the configuration in which the capacitor 122 is disposed in parallel with the part 112a of the wire 112, the part 112a of the wire 112 and the capacitor 122 can function as an LC tank circuit in the fundamental wave band of the balanced signals. This in turn makes it possible to properly match the impedance between the differential pair upstream of the balun 101 and a circuit downstream of the balun 101 and thereby makes it possible to reduce the reflection of the fundamental waves of the balanced signals. In the second-order harmonic wave band of the balanced signals, the parallel circuit formed by the part 111a of the wire 111 and the capacitor 121 prominently exhibits the property of a capacitor, and therefore the wire 111 and the capacitor 121 together function as with an LC series circuit. Also, the parallel circuit formed by the part 112a of the wire 112 and the capacitor 122 prominently exhibits the property of a capacitor, and therefore the wire 112 and the capacitor 122 together function as with an LC series circuit. That is, each of the combination of the wire 111 and the capacitor 121 and the combination of the wire 112 and the capacitor 122 can function as a notch filter that shorts in the second-order harmonic wave band of the balanced signals. This makes it possible to reduce the impedance of the second-order harmonic waves of the balanced signals and thereby enables the differential pair upstream of the balun 101 to operate in Class F without providing separate notch filters. Thus, the above configuration enables amplifiers to operate in Class F while reducing an increase in the circuit size.

In the balun 101, each of the wires 111 and 112 is a quarter-wave line. Also, a wire formed by the combination of the wires 113 and 114 is a half-wave line.

This configuration makes it possible to properly convert balanced signals into an unbalanced signal and convert an unbalanced signal into balanced signals.

Also, in the balun 101, the frequency of balanced signals is included in the sub-terahertz band.

For example, when a magnetically coupled transformer (MCT) balun is used in the sub-terahertz band, the loss may increase due to the large parasitic capacitance between the wires of the transformer, and the MCT balun may fail to achieve its inherent performance. With the balun 101 used in the sub-terahertz band, the wires 111 to 114 can be made short, and therefore the increase in the circuit size can be reduced. Also, with a configuration using the balun 101 having a large fractional bandwidth and implemented by low-loss line coupling, it is possible to provide the balun 101 with excellent performance.

Also, in the balun 101, the electrical length of the part 111a of the wire 111 and the electrical length of the part 112a of the wire 112 are substantially the same.

This configuration makes it possible to reduce the imbalance between the electrical characteristics of the wire 111 and the electrical characteristics of the wire 112 and thereby makes it possible to more properly convert balanced signals into an unbalanced signal and convert an unbalanced signal into balanced signals.

In the balun 101, the wire 111 is formed by the metal electrode 611 that is provided along the first surface and extends from the first end of the wire 111 to the second end of the wire 111. The metal electrode 611 includes the corner part 611c that forms the part 111a of the wire 111 and at which the extension direction of the metal electrode 611 changes. The capacitor 121 is disposed outward of the corner part 611c.

With this configuration, for example, a space for the capacitor 121 can be easily secured by truncating the outer side of the corner part 611c. This in turn makes it easier to design the layout of the balun 101 in a semiconductor chip. Moreover, this configuration makes it possible to effectively use space and thereby makes it possible to improve the integration density of a semiconductor chip.

Also, in the balun 101, the wire 112 is formed by the metal electrode 612 that is provided along the first surface and extends from the first end of the wire 112 to the second end of the wire 112. The metal electrode 612 includes the corner part 612c that forms the part 112a of the wire 112 and at which the extension direction of the metal electrode 612 changes. The capacitor 122 is disposed outward of the corner part 612c.

With this configuration, for example, a space for the capacitor 122 can be easily secured by truncating the outer side of the corner part 612c. This in turn makes it easier to design the layout of the balun 101 in a semiconductor chip. Moreover, this configuration makes it possible to effectively use space and thereby makes it possible to improve the integration density of a semiconductor chip.

Also, in the balun 101, the wire 113 is formed by the metal electrode 613 that is provided along the first surface and extends from the first end of the wire 113 to the second end of the wire 113. The metal electrode 613 includes the corner part 613c that is disposed inward of the corner part 611c and extends alongside the corner part 611c.

With the configuration in which the corner part 613c is disposed opposite to the capacitor 121, the corner part 613c can be laid out at a constant distance from the corner part 611c without being blocked by the capacitor 121. This in turn makes it possible to achieve proper electromagnetic coupling between the corner parts 611c and 613c.

In the balun 101, the wire 114 is formed by the metal electrode 614 that is provided along the first surface and extends from the first end of the wire 114 to the second end of the wire 114. The metal electrode 614 includes the corner part 614c that is disposed inward of the corner part 612c and extends alongside the corner part 612c.

With the configuration in which the corner part 614c is disposed opposite to the capacitor 122, the corner part 614c can be laid out at a constant distance from the corner part 612c without being blocked by the capacitor 122. This in turn makes it possible to achieve proper electromagnetic coupling between the corner parts 612c and 614c.

In the balun 101, the wire 111 is formed by the metal electrode 611 that is provided along the first surface and extends from the first end of the wire 111 to the second end of the wire 111. The metal electrode 611 includes the corner part 611c that forms the part 111a of the wire 111 and at which the extension direction of the metal electrode 611 changes. The wire 112 is formed by the metal electrode 612 that is provided along the first surface and extends from the first end of the wire 112 to the second end of the wire 112. The metal electrode 612 includes the corner part 612c that forms the part 112a of the wire 112 and at which the extension direction of the metal electrode 612 changes. The metal electrode 611 includes the extension parts 611a and 611b that are connected to the corner part 611c. The metal electrode 612 includes the extension parts 612a and 612b that are connected to the corner part 612c. The extension parts 611a and 612a extend toward each other from the corner parts 611c and 612c, respectively. The extension parts 611b and 612b extend in the same direction from the corner parts 611c and 612c, respectively.

With this configuration, it is possible to lay out metal electrodes, including the extension part 611b, the corner part 611c, the extension part 611a, the extension part 612a, the corner part 612c, and the extension part 612b, in a substantially U-shape and thereby makes it possible to secure a space for the wires 113 and 114 inside of the U-shape.

In the power amplifier circuit 201, the amplifier 51p amplifies the signal RFp2 and outputs the amplified signal RFp3 from the output terminal 51pa. The amplifier 51m amplifies the signal RFm2, which is out of phase with the signal RFp2, and outputs the amplified signal RFm3 from the output terminal 51ma. The wire 111 includes the first end connected to the output terminal 50pa and the second end connected to the first reference potential. The wire 112 includes the first end connected to the output terminal 50ma and the second end connected to the first reference potential. The wire 113 includes the first end and the open second end and is electromagnetically coupled to the wire 111. The wire 114 includes the first end connected to the first end of the wire 113 and the second end connected to the output terminal 32, and is electromagnetically coupled to the wire 112. The capacitor 121 is connected in parallel with the part 111a of the wire 111. The capacitor 122 is connected in parallel with the part 112a of the wire 112.

With this configuration in which the capacitor 121 is disposed in parallel with the part 111a of the wire 111, the part 111a of the wire 111 and the capacitor 121 can function as an LC tank circuit in the fundamental wave band of the signals RFp2 and RFm2. Similarly, with the configuration in which the capacitor 122 is disposed in parallel with the part 112a of the wire 112, the part 112a of the wire 112 and the capacitor 122 can function as an LC tank circuit in the fundamental wave band of the signals RFp2 and RFm2. This makes it possible to properly match the impedance between the amplifiers 51p and 51m and a circuit downstream of the balun 101 and thereby makes it possible to reduce the reflection of the fundamental waves of the signals RFp2 and RFm2. In the second-order harmonic wave band of the signals RFp2 and RFm2, the parallel circuit formed by the part 111a of the wire 111 and the capacitor 121 prominently exhibits the property of a capacitor, and therefore the wire 111 and the capacitor 121 together function as with an LC series circuit. Also, the parallel circuit formed by the part 112a of the wire 112 and the capacitor 122 prominently exhibits the property of a capacitor, and therefore the wire 112 and the capacitor 122 together function as with an LC series circuit. That is, each of the combination of the wire 111 and the capacitor 121 and the combination of the wire 112 and the capacitor 122 can function as a notch filter that shorts in the second-order harmonic wave band of the signals RFp2 and RFm2. This in turn makes it possible to reduce the impedance of the second-order harmonic wave of the signals RFp2 and RFm2 and thereby enable the amplifiers 51p and 51m to operate in Class F without providing separate notch filters. Thus, the above configuration enables amplifiers to operate in Class F while reducing an increase in the circuit size.

The above-described embodiments are intended to facilitate the understanding of the present disclosure and are not intended to limit the interpretation of the present disclosure. The present disclosure may be modified or improved without departing from the spirit of the present disclosure, and the present disclosure may include its equivalents. That is, any embodiment implemented by a person skilled in the art by changing any of the above embodiments may be included in the scope of the present disclosure as long as the implemented embodiment includes features of the present disclosure. For example, elements in the embodiments and their arrangements, materials, conditions, shapes, sizes, etc., are not limited to the examples described in the embodiments and can be modified as necessary. Needless to say, the embodiments are examples. Partial substitutions and combinations of components in different embodiments may be made, and resulting embodiments are also included in the scope of the present disclosure as long as those embodiments include features of the present disclosure.
<1> A balun includes a first wire including a first end connected to a first balanced line transmitting one of balanced signals and a second end connected to a first reference potential; a second wire including a first end connected to a second balanced line transmitting another one of the balanced signals and a second end connected to the first reference potential; a third wire that includes a first end and an open second end and is electromagnetically coupled to the first wire; a fourth wire that includes a first end connected to the first end of the third wire and a second end connected to an unbalanced line transmitting an unbalanced signal and is electromagnetically coupled to the second wire; a first capacitor connected in parallel with a part of the first wire; and a second capacitor connected in parallel with a part of the second wire.
<2> In the balun described in <1>, each of the first wire and the second wire is a quarter-wave line, and a wire formed by a combination of the third wire and the fourth wire is a half-wave line.
<3> In the balun described in <1> or <2>, the frequency of the balanced signals is included in a sub-terahertz band.
<4> In the balun described in any one of <1> to <3>, the electrical length of the part of the first wire and the electrical length of the part of the second wire are substantially equal to each other.
<5> In the balun described in any one of <1> to <4>, the first wire is formed by a first conductive component that is provided along a first surface and extends from the first end of the first wire to the second end of the first wire, the first conductive component includes a first corner part that forms the part of the first wire and at which an extension direction of the first conductive component changes, and the first capacitor is disposed outward of the first corner part.
<6> In the balun described in any one of <1> to <5>, the second wire is formed by a second conductive component that is provided along a first surface and extends from the first end of the second wire to the second end of the second wire, the second conductive component includes a second corner part that forms the part of the second wire and at which an extension direction of the second conductive component changes, and the second capacitor is disposed outward of the second corner part.
<7> In the balun described in <5>, the third wire is formed by a third conductive component that is provided along the first surface and extends from the first end of the third wire to the second end of the third wire, and the third conductive component includes a third corner part that is disposed inward of the first corner part and extends alongside the first corner part.
<8> In the balun described in <6>, the fourth wire is formed by a fourth conductive component that is provided along the first surface and extends from the first end of the fourth wire to the second end of the fourth wire, and the fourth conductive component includes a fourth corner part that is disposed inward of the second corner part and extends alongside the second corner part.
<9> In the balun described in any one of <1> to <8>, the first wire is formed by a first conductive component that is provided along a first surface and extends from the first end of the first wire to the second end of the first wire; the first conductive component includes a first corner part that forms the part of the first wire and at which an extension direction of the first conductive component changes; the second wire is formed by a second conductive component that is provided along the first surface and extends from the first end of the second wire to the second end of the second wire; the second conductive component includes a second corner part that forms the part of the second wire and at which an extension direction of the second conductive component changes; the first conductive component includes a first extension part and a second extension part that are connected to the first corner part; the second conductive component includes a third extension part and a fourth extension part that are connected to the second corner part; the first extension part and the third extension part extend toward each other from the first corner part and the second corner part, respectively; and the second extension part and the fourth extension part extend in a same direction from the first corner part and the second corner part, respectively.
<10> A power amplifier circuit includes a first amplifier that amplifies a first signal and outputs a first amplified signal from a first output terminal; a second amplifier that amplifies a second signal, which is out of phase with the first signal, and outputs a second amplified signal from a second output terminal; a first wire including a first end connected to the first output terminal and a second end connected to a first reference potential; a second wire including a first end connected to the second output terminal and a second end connected to the first reference potential; a third wire that includes a first end and an open second end and is electromagnetically coupled to the first wire; a fourth wire that includes a first end connected to the first end of the third wire and a second end connected to an output terminal and is electromagnetically coupled to the second wire; a first capacitor connected in parallel with a part of the first wire; and a second capacitor connected in parallel with a part of the second wire.

What is claimed is:

1. A balun comprising:
a first wire having a first end connected to a first balanced line transmitting one of a set of balanced signals, and a second end connected to a first reference potential;
a second wire having a first end connected to a second balanced line transmitting another one of the set of balanced signals, and a second end connected to the first reference potential;
a third wire that has a first end and an open second end, and is electromagnetically coupled to the first wire;
a fourth wire that has a first end connected to the first end of the third wire, and a second end connected to an unbalanced line transmitting an unbalanced signal, and that is electromagnetically coupled to the second wire;
a first capacitor connected in parallel with a part of the first wire; and
a second capacitor connected in parallel with a part of the second wire.

2. The balun according to claim 1,
wherein each of the first wire and the second wire is a quarter-wave line; and
wherein a wire formed by a combination of the third wire and the fourth wire is a half-wave line.

3. The balun according to claim 1, wherein a frequency of the balanced signals is included in a sub-terahertz band.

4. The balun according to claim 1, wherein an electrical length of the part of the first wire and an electrical length of the part of the second wire are equal to each other.

5. The balun according to claim 1,
wherein the first wire is formed by a first conductive component that is along a first surface and that extends from the first end of the first wire to the second end of the first wire,
wherein the first conductive component has a first corner part that forms the part of the first wire and at which an extension direction of the first conductive component changes, and
wherein the first capacitor is disposed outward of the first corner part.

6. The balun according to claim 1,
wherein the second wire is formed by a second conductive component that is along a first surface and that extends from the first end of the second wire to the second end of the second wire,
wherein the second conductive component has a second corner part that forms the part of the second wire and at which an extension direction of the second conductive component changes, and
wherein the second capacitor is disposed outward of the second corner part.

7. The balun according to claim 5,
wherein the third wire is formed by a third conductive component that is along the first surface and that extends from the first end of the third wire to the second end of the third wire, and
the third conductive component has a third corner part that is disposed inward of the first corner part and that extends alongside the first corner part.

8. The balun according to claim 6,
wherein the fourth wire is formed by a fourth conductive component that is along the first surface and that extends from the first end of the fourth wire to the second end of the fourth wire, and
wherein the fourth conductive component has a fourth corner part that is disposed inward of the second corner part and that extends alongside the second corner part.

9. The balun according to claim 1,
wherein the first wire is formed by a first conductive component that is along a first surface and that extends from the first end of the first wire to the second end of the first wire,
wherein the first conductive component has a first corner part that forms the part of the first wire and at which an extension direction of the first conductive component changes,
wherein the second wire is formed by a second conductive component that is along the first surface and that extends from the first end of the second wire to the second end of the second wire,
wherein the second conductive component has a second corner part that forms the part of the second wire and at which an extension direction of the second conductive component changes,
wherein the first conductive component has a first extension part and a second extension part that are connected to the first corner part,
wherein the second conductive component has a third extension part and a fourth extension part that are connected to the second corner part,
wherein the first extension part and the third extension part extend toward each other from the first corner part and the second corner part, respectively, and
wherein the second extension part and the fourth extension part extend in a same direction from the first corner part and the second corner part, respectively.

10. A power amplifier circuit comprising:
a first amplifier configured to amplify a first signal and to output a first amplified signal from a first output terminal;
a second amplifier configured to amplify a second signal, which is out of phase with the first signal, and to output a second amplified signal from a second output terminal;
a first wire having a first end connected to the first output terminal, and a second end connected to a first reference potential;
a second wire having a first end connected to the second output terminal, and a second end connected to the first reference potential;
a third wire that has a first end and an open second end, and that is electromagnetically coupled to the first wire;
a fourth wire that has a first end connected to the first end of the third wire, and a second end connected to an output terminal, and that is electromagnetically coupled to the second wire;
a first capacitor connected in parallel with a part of the first wire; and
a second capacitor connected in parallel with a part of the second wire.
